(19) United States
(12) Patent Application Publication
(10) Pub. No.: US 2026/0349348 A1
(43) Pub. Date: Nov. 5, 2026

(54) IMAGING OPTICAL UNIT FOR IMAGING AN OBJECT FIELD INTO AN IMAGE FIELD, AND PROJECTION EXPOSURE APPARATUS HAVING SUCH AN IMAGING OPTICAL UNIT

(71) Applicant: Carl Zeiss SMT GmbH, Oberkochen (DE)

(72) Inventors: Andreas HOFMAIER, Heidenheim (DE); Tanja MUELLER, Heidenheim (DE); Jessica HAEGELE, Heuchlingen (DE); Mark FEYGIN, Aalen (DE)

(21) Appl. No.: 19/682,493

(22) Filed: May 20, 2026

Related U.S. Application Data
(63) Continuation of application No. PCT/EP2024/082315, filed on Nov. 14, 2024.

(30) Foreign Application Priority Data
Nov. 21, 2023 (DE) 10 2023 211 589.1
Nov. 21, 2023 (DE) 10 2023 211 590.5

(51) Int. Cl. G03F 7/00; G02B 17/06

(52) U.S. Cl. CPC G03F 7/7025; G02B 17/0663; G03F 7/70233

(57) ABSTRACT

An imaging optical unit for projection lithography has a plurality of mirrors for imaging an object field in an object plane into an image field in an image plane with imaging light guided along a beam path between these fields. A penultimate mirror in the beam path has no passage opening for the imaging light. A stop is in the beam path between the penultimate mirror in the beam path and a last mirror in the beam path. It specifies an outer edge contour of a pupil of the imaging optical unit in the beam path between the penultimate mirror and the last mirror, at least in one pupil edge contour portion located in the beam path between the last mirror in the beam path and the image field at the same time.

### CROSS-REFERENCE TO RELATED APPLICATIONS

The present application is a continuation of, and claims benefit under 35 USC 120 to, international application No. PCT/EP2024/082315, filed Nov. 14, 2024, which claims benefit under 35 USC 119 of German Application Nos. 10 2023 211 589.1 and 10 2023 211 590.5, both filed Nov. 21, 2023. The entire disclosure of each of these applications is incorporated by reference herein.

### FIELD

The disclosure relates to an imaging optical unit for imaging an object field into an image field. Furthermore, the disclosure relates to an optical system having such an imaging optical unit, a projection exposure apparatus having such an optical system, a method for producing a microstructured or nanostructured component by such a projection exposure apparatus, and a microstructured or nanostructured component produced by the method.

### BACKGROUND

Projection optical units are known from WO 2016/188934 A1, from DE 10 2015 209 827 A1, from DE 10 2012 212 753 A1, from US 2010/0149509 A1 and from US 4,964,706. DE 10 2020 207 022 A1 discloses an optical system of a lithography apparatus, comprising an obscuration stop. DE 10 2015 011 933 B3 discloses a method and use of an electronic visual display for the secure presentation of information. DE 10 2015 210 041 A1 discloses an optical system of a microlithographic projection exposure apparatus. DE 10 2022 105 167 A1 discloses a lighting device for a vehicle for ensuring a dark or coloured appearance of at least one part of the lighting device when switched off. DE 10 2015 221 985 A1 discloses an imaging optical unit for imaging an object field into an image field and a projection exposure apparatus having such an imaging optical unit. DE 10 2021 204 582 B3 discloses an optical system and a projection exposure apparatus.

### SUMMARY

The present disclosure seeks to develop an imaging optical unit having a relatively well defined pupil and improved for projection lithography results.

In a first aspect, the disclosure provides an imaging optical unit for projection lithography. The imaging optical unit comprises a plurality of mirrors for imaging an object field in an object plane into an image field in an image plane with imaging light guided along a beam path between the object field and the image field. The plurality of mirrors comprises a penultimate mirror in the beam path without a passage opening for passage of the imaging light. A stop is arranged in the beam path between the penultimate mirror in the beam path and a last mirror in the beam path. The stop is embodied such that it specifies an outer edge contour of a pupil of the imaging optical unit in the beam path between the penultimate mirror in the beam path and the last mirror in the beam path, at least in one pupil edge contour portion located in the beam path between the last mirror in the beam path and the image field at the same time.

The disclosure recognized that it is possible to also delimit an outer edge contour of a pupil of the imaging optical unit in a beam path using a stop which is located between a last mirror of the imaging optical unit in the beam path and the image field at the same time from the beam path. According to the disclosure, the stop can be designed in a way that accepts a corresponding shading effect for the beam path by the stop between the last mirror in the beam path and the image field. The stop can be an aperture stop for specifying an image field-side numerical aperture of the imaging optical unit. In addition, the stop can also be embodied as an obscuration stop for specifying an inner edge contour of the pupil. The aperture stop, for specifying the outer edge contour and/or the obscuration stop for specifying the inner edge contour of the pupil, can in each case be embodied in one piece or in one part. In an alternative, the aperture stop and/or the obscuration stop can also be embodied in many parts.

By way of such a stop, the outer edge contour of the pupil can also be specified in the pupil edge contour portion located in the beam path between the last mirror in the beam path and the image field at the same time. The result can then be an overall precise pupil specification.

In embodiments, the stop shades less than 1% of the beam path between the last mirror in the beam path and the image field within an image field-side numerical aperture specified by the stop. Such embodiments can yield a tolerably low loss of throughput in which the stop shades less than 1% of a cross section of the beam path between the last mirror in the beam path and the image field within the image field-side numerical aperture specified by the stop.

In embodiments, the imaging optical unit further comprises at least one stop partial sleeve portion with at least one sleeve portion wall, which specifies the outer edge contour of the pupil in the pupil edge contour portion and extends along the beam path between the last mirror in the beam path and the image field. Such embodiments can help enable a particularly low loss of throughput. The at least one sleeve portion wall extending along the beam path between the last mirror and the image field can lead only to slight shading of the imaging light for this component beam path.

In embodiments, the imaging optical unit further comprises a plurality of stop partial sleeve portions each with a sleeve portion wall, which in each case specifies, at least in portions, the outer edge contour of the pupil in the pupil edge contour portion and extends along the beam path between the last mirror in the beam path and the image field. Such embodiments can help allow particularly precise pupil specification and/or particularly good stray light suppression. The various sleeve portion walls of the stop partial sleeve portions can specify the same pupil edge contour portion or else different, complementary pupil edge contour portions.

In embodiments, stop partial sleeve portions are connected to one another. This can help avoid the need to independently hold each of the plurality of stop partial sleeve portions on an outer carrier component.

In embodiments, a wall thickness of the at least one sleeve portion wall is less than 0.5 mm. This can help enable a particularly low loss of throughput of the imaging light which is caused by a shading of the stop.

In embodiments, the last mirror in the beam path has a passage opening for passage of the imaging light the case of an imaging optical unit. Such a stop can come into effect particularly well, especially when embodied as an obscuration stop.

In embodiments, the stop covers the outer edge contour of the pupil in an azimuth range, greater than 180°, around a centre of the pupil. Such an azimuthal cover can have the consequence that, if at all, only a small pupil azimuth range not specified by the stop remains. The azimuth range specified by the stop can be 200°, 220°, 240° or be even greater. In the extreme case, the azimuth range is 360°. In this case, the stop delimits the pupil edge contour over the entire circumference.

In embodiments, the stop is embodied such that it specifies the entire outer edge contour of the pupil of the imaging optical unit. This can help lead to a particularly good pupil definition.

In a second aspect, the disclosure provides an imaging optical unit for projection lithography. The imaging optical unit comprises a plurality of mirrors for imaging an object field in an object plane into an image field in an image plane with imaging light guided along a beam path between the object field and the image field. The plurality of mirrors comprises a penultimate mirror in the beam path without a passage opening for passage of the imaging light. A stop is arranged in the beam path between the penultimate mirror in the beam path and a last mirror in the beam path. The stop is embodied such that it specifies an edge contour of a pupil of the imaging optical unit in the beam path between the penultimate mirror in the beam path and the last mirror in the beam path, at least in portions. The stop is fastened to a component of the imaging optical unit via a securing element which at least in portions extends along the beam path between the penultimate mirror in the beam path and the last mirror in the beam path. Features of imaging optical unit according to the second aspect can correspond in general to those which have explained above with reference to the first aspect and embodiment variants.

Despite the fact that a plurality of imaging light component beams pass through an installation space between the penultimate mirror in the beam path and the last mirror in the beam path, the installation space can be suitable for arranging a pupil-defining stop. This can make use of the circumstance that one of the imaging light component beams passing through in the installation space between the penultimate and last mirrors can be generally significantly larger than the other imaging light component beams with regard to its diameter, and so a marginal delimitation at any rate of an outer edge contour portion of the pupil of the imaging optical unit can be possible there. The imaging optical unit can have exactly one object field and can have exactly one image field. The imaging optical unit can have an entrance pupil arranged in the beam path of illumination and imaging light upstream of the object field. The imaging optical unit can correspondingly have a negative front focal length or a negative input pupil position. In the case of such imaging optical units, the arrangement of a stop spatially between the last two mirrors in the beam path has been found to be particularly suitable. It is then possible to realize a well corrected imaging optical unit having a high image-side numerical aperture. The stop can have a bent profile. The imaging optical unit can comprise at least one GI mirror, i.e. a grazing incidence mirror having an angle of incidence that is greater than 45°. The angle of incidence on the GI mirror can be greater than 50°, can be greater than 55°, can be greater than 60°, can be greater than 65°, can be greater than 70°, can be greater than 75° and can be greater than 80°. The effect of the stop as an aperture stop can be brought about by the shading of the beam path between the penultimate mirror in the beam path and the last mirror in the beam path of the imaging optical unit. The imaging optical unit can have exactly one stop for specifying at least one portion of an outer edge contour of a pupil of the imaging optical unit. In an alternative, provision can be made of a plurality of such stops for specifying portions of the outer edge contour of the pupil of the imaging optical unit that supplement one another for example complementarily. In addition to the stop specifying the outer edge contour of the pupil, provision can be made for an obscuration stop for specifying an inner edge contour of an obscuration of the pupil. A securing element which is used for fastening the stop and which extends at least in portions along the beam path between the penultimate mirror in the beam path and the last mirror in the beam path of the imaging optical unit can be designed such that, if at all, only a small loss of throughput of imaging light results due to shading by the securing element. For example, shading losses of the imaging light in the beam path between the penultimate mirror and the last mirror can be minimized or even completely avoided. The securing element can be arranged extending in portions or in full along an obscured beam path portion of the beam path of the imaging optical unit, i.e. along a beam path portion shaded by other components of the imaging optical unit, for example by an obscuration stop; this reduces or even completely avoids losses of throughput. The securing element can comprise a plurality of securing connecting pieces. The securing element can comprise a central connecting piece that extends along an obscured beam path portion. To fasten such a central connecting piece, the securing element can comprise at least one further connecting piece.

The disclosure recognized that a shading effect of the securing element in the beam path between the last mirror and the image field can be tolerated if a shading cross section of the securing element is correspondingly small.

A securing element according to the second aspect can be particularly suitable for securing an obscuration stop.

In embodiments, the pupil of the imaging optical unit is obscured, and the stop is embodied such that it specifies the inner edge contour of the obscured pupil of the imaging optical unit in the beam path between the penultimate mirror in the beam path and the last mirror in the beam path. This can represent an obscuration stop which defines an inner obscuration of the pupil of the imaging optical unit. When fastening such an obscuration stop, the features of the variants of securing elements discussed above come into effect particularly well. The securing element may be located in portions or in full in the beam path of the imaging optical unit shaded by the obscuration stop.

In embodiments, the securing element is fastened to: the last mirror in the beam path; the penultimate mirror in the beam path; or an antepenultimate mirror in the beam path; or a frame component of the imaging optical unit. Such embodiments have proven their worth and are used depending on the desired structural properties of the imaging optical unit. Mixed forms of these embodiments may also be used, i.e. for example a securing element fastened both to at least one of the mirrors and to one of the frame components of the imaging optical unit or a securing element fastened to at least two of the mirrors.

In a third aspect, the disclosure provides an imaging optical unit for projection lithography. The imaging optical unit comprises a plurality of mirrors for imaging an object field in an object plane into an image field in an image plane with imaging light guided along a beam path between the object field and the image field. The plurality of mirrors comprises a penultimate mirror in the beam path without a passage opening for passage of the imaging light. A stop is arranged in the beam path between the penultimate mirror in the beam path and a last mirror in the beam path. The stop is: part of an enveloping component of the imaging optical unit surrounding the beam path; or fastened to an enveloping component of the imaging optical unit surrounding the beam path; or fastened to a frame component of the imaging optical unit; or fastened to the penultimate mirror in the beam path; or fastened to the last mirror in the beam path.

Features of an imaging optical unit according to third aspect can correspond to those explained above with reference to imaging optical units of the first and/or second aspects and corresponding embodiment variants. The arrangement or fastening variants according to the third aspect can in turn allow defined positioning of an aperture stop and/or an obscuration stop. A position definition of the stop according to any of the variants of the third aspect can be particularly suitable for precise positioning of an aperture stop.

The enveloping component can be a component for enclosing the beam path. Such an enveloping component can serve for a clean environment for at least one mirror of the imaging optical unit surrounded by the enveloping component. Within the enveloping component, a finite hydrogen partial pressure within the imaging optical unit can be created by an associated hydrogen source, and so constant contact with hydrogen and with hydrogen radicals for example can be provided adjacent to at least one of the reflection surfaces of the imaging optical unit. This can be used to clean the at least one mirror or to avoid contamination thereof. The enveloping component can be embodied to suppress stray light that does not run along the specified beam path of the imaging optical unit. The enveloping component can at least in portions comprise a functional coating facing the beam path. This functional coating can have an effect that absorbs extraneous light/stray light in defined fashion. In an alternative to that or in addition, the functional coating can have an adhesive effect for contamination particles, and so corresponding contamination particles cannot reach or find it difficult to reach reflection surfaces of the imaging optical unit.

In embodiments, the imaging optical unit further comprises a securing element for fastening: the stop to the enveloping component surrounding the beam path; the stop to the frame component; or the antepenultimate mirror in the beam path; or the penultimate mirror in the beam path; or the last mirror in the beam path. The securing element is located at least in portions in a beam path between the last mirror in the beam path and the image field. Such embodiments have proven their worth depending on the structural and desired optical properties of the imaging optical unit. Mixed forms of these securing element variants can be used, for example fastening the stop both to at least one of the frame components and to the at least one enveloping component.

In embodiments, the securing element shades less than 1% of the beam path between the last mirror in the beam path and the image field within an image field-side numerical aperture specified by the stop. This can help ensure little shading of the beam path.

In embodiments, a wall thickness of the securing element is less than 0.5 mm. This can yield a small shading cross section.

In embodiments, the last mirror in the beam path has a passage opening for passage of the imaging light. In such embodiments, the stop can come into effect particularly well, especially when embodied as an obscuration stop.

In embodiments, the stop covers an outer edge contour of the pupil in an azimuth range, greater than 180°, around a centre of the pupil. Such an azimuthal cover can have the consequence that, if at all, only a small pupil azimuth range not specified by the stop remains. The azimuth range specified by the stop can be 200°, 220°, 240° or be even greater. In the extreme case, the azimuth range is 360°. In this case, the stop delimits the pupil edge contour over the entire circumference.

In embodiments, the stop is embodied such that it specifies the entire outer edge contour of the pupil and/or that it specifies the entire inner edge contour of the pupil. This can help lead to a particularly good pupil definition.

The aperture stop for specifying the outer edge contour and/or the obscuration stop for specifying the inner edge contour of the pupil can in each case be embodied in one piece or in one part. In an alternative, the aperture stop and/or the obscuration stop can also be embodied in many parts.

The features of an imaging optical unit according to the first, second and/or third aspects, as well as their embodiment variants, can be combined with one another.

In a fourth aspect, the disclosure provides an optical system comprising: an illumination optical unit for illuminating the object field with the imaging light; and an imaging optical unit according to the disclosure. Features of such an optical system can correspond to those explained above with reference to an imaging optical unit according to the disclosure.

In a fifth aspect, the disclosure provides an optical system comprising: an imaging optical unit according to the disclosure; and a wafer holder for displacing a wafer along an object displacement direction. The stop delimits both extreme edge positions of the outer edge contour of the pupil of the imaging optical unit in a direction perpendicular to the object displacement direction. Features of such an optical system can correspond for example to certain of those explained above.

In a sixth aspect, the disclosure provides a projection exposure apparatus having an optical system according to the disclosure and an EUV light source.

In a seventh aspect, the disclosure provides a method for producing a structured component comprising the following method steps: providing a reticle and a wafer; projecting a structure on the reticle onto a light-sensitive layer of the wafer using a projection exposure apparatus according to the disclosure; and creating a microstructure or nanostructure on the wafer.

In an eighth aspect, the disclosure provides a structured component, produced by a method according to the disclosure.

Features of the sixth, seventh and/or eighth aspect can correspond to those explained above with regard to preceding aspects and/or embodiment variants.

A structured component can be, for example, a semiconductor component, such as a memory chip.

### BRIEF DESCRIPTION OF THE DRAWINGS

Exemplary embodiments of the disclosure are explained in detail below with reference to the drawing, in which:

FIG. 1 schematically shows a projection exposure apparatus for EUV microlithography;

FIG. 2 shows, in a meridional section, principal components of an imaging optical unit which can be used as a projection lens in the projection exposure apparatus according to FIG. 1, wherein an imaging beam path for chief rays and for an upper coma ray and a lower coma ray of a plurality of selected field points is depicted;

FIG. 3A shows, in a detail enlargement of FIG. 2 mirrored about the xz-plane, part of the imaging optical unit including a component beam path between an antepenultimate mirror of the imaging optical unit and an image field, the marginally delimiting rays of which are emphasized, wherein additionally a portion of a stop, embodied as an aperture stop, is arranged in the beam path between a penultimate mirror in the beam path and the last mirror in the beam path, the stop comprising exactly one stop partial sleeve portion;

FIG. 3B shows the detail IIIa in FIG. 3A in enlarged fashion;

FIG. 4 shows the section according to FIG. 3A in perspective obliquely from below, wherein an aperture-delimiting portion profile of a portion of the stop is illustrated and the stop partial sleeve portion is omitted;

FIG. 5 shows, in an illustration similar to FIG. 3, a further embodiment of a stop, once again embodied as an aperture stop, comprising a plurality of stop partial sleeve portions;

FIG. 6 shows a portion of the imaging optical unit according to FIG. 2 in the region of for example a penultimate mirror and a last mirror of the imaging optical unit for the purpose of illustrating a further embodiment of the imaging optical unit, wherein marginal rays of the imaging beam path and a stop in the form of an obscuration stop for specifying an edge contour of an obscuration of a pupil of the imaging optical unit in the beam path between the penultimate mirror in the beam path and the last mirror in the beam path are shown, wherein a first embodiment of fastening the stop to the last mirror in the beam path by way of a securing element is illustrated, the latter extending along a beam path between the penultimate mirror in the beam path and the last mirror in the beam path;

FIG. 7 shows, in an illustration similar to FIG. 6, a further embodiment of fastening the stop, once again to the last mirror in the beam path;

FIG. 8 shows a plan view of a securing element of the fastening according to FIG. 7, as seen along the viewing direction VIII in FIG. 7 through a passage opening in the last mirror of the imaging optical unit in the beam path;

FIG. 9 shows, in an illustration similar to FIG. 6, a further embodiment of fastening the stop to an antepenultimate mirror of the imaging optical unit in the beam path;

FIG. 10 shows, in an illustration similar to FIG. 6, a stop once again arranged in the beam path between the penultimate mirror in the beam path and the last mirror in the beam path, embodied as an aperture stop for specifying an image field-side numerical aperture of the imaging optical unit, wherein the stop is part of an enveloping component of the imaging optical unit surrounding the beam path of the imaging optical unit;

FIG. 11 shows a plan view of the stop of the embodiment according to FIG. 10 according to the viewing direction XI, wherein a section according to line X-X in FIG. 11 results in the meridional section according to FIG. 10;

FIG. 12 shows, in an illustration similar to FIG. 10, a stop portion of a further embodiment of an aperture stop for specifying the image-side numerical aperture of the imaging optical unit, wherein the stop portion is fastened to an enveloping component of the imaging optical unit surrounding the beam path;

FIG. 13 shows, in an illustration similar to FIG. 12, a further stop portion of the aperture stop, likewise fastened to an enveloping component of the imaging optical unit surrounding the beam path;

FIG. 14 shows, in an illustration similar to FIG. 12, a variant of fastening the stop portion according to FIG. 12 to a frame component of the imaging optical unit;

FIGS. 15 and 16 show, in an illustration similar to FIG. 13, two variants of fastening the stop portion according to FIG. 13 to a frame component of the imaging optical unit;

FIG. 17 shows, in an illustration similar to FIG. 12, an embodiment of fastening the stop portion according to FIG. 12 to the penultimate mirror in the beam path; and

FIG. 18 shows, in an illustration similar to FIG. 13, an embodiment of fastening the stop portion according to FIG. 13 to the penultimate mirror in the beam path.

### DETAILED DESCRIPTION

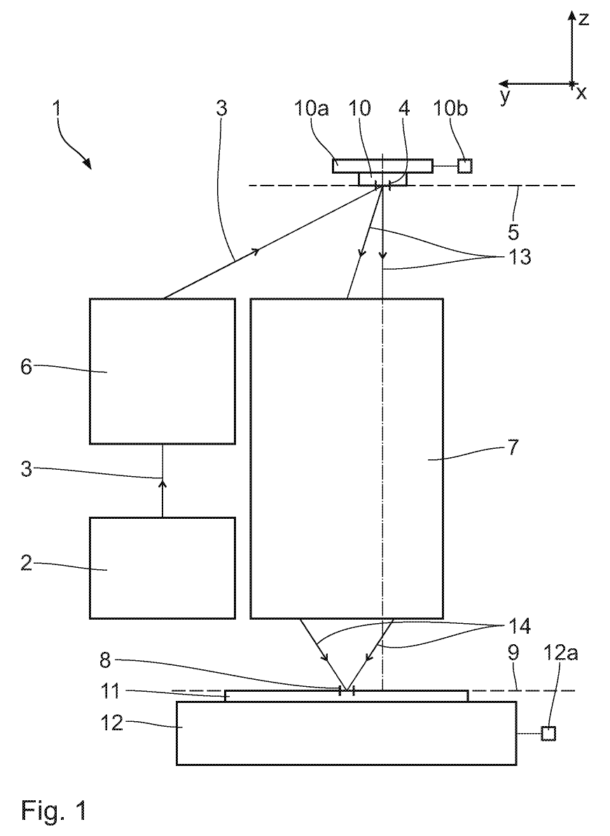

A microlithographic projection exposure apparatus 1 has a light source 2 for illumination light or imaging light 3. The light source 2 is an EUV light source, which creates light in a wavelength range of, for example, between 5 nm and 30 nm, for example between 5 nm and 15 nm. For example, the light source 2 can be a light source with a wavelength of 13.5 nm or a light source with a wavelength of 6.9 nm. Other EUV wavelengths are also possible. In general, it is even possible to use any desired wavelengths for the illumination light 3 guided in the projection exposure apparatus 1, for example visible wavelengths or else other wavelengths which may find use in microlithography (for example DUV, deep ultraviolet) and for which suitable laser light sources and/or LED light sources are available (e.g. 365 nm, 248 nm, 193 nm, 157 nm, 129 nm, 109 nm). A beam path of the illumination light 3 is depicted very schematically in FIG. 1.

An illumination optical unit 6 is used to guide the illumination light 3 from the light source 2 to an object field 4 in an object plane 5. Using a projection optical unit or imaging optical unit 7, the object field 4 is imaged into an image field 8 in an image plane 9 with a specified reduction scale. The projection optical unit 7 has exactly one object field 4. The projection optical unit 7 has exactly one image field 8.

In order to facilitate the description of the projection exposure apparatus 1 and the various embodiments of the projection optical unit 7, a Cartesian xyz-coordinate system is indicated in the drawing, from which system the respective positional relationship of the components illustrated in the figures is evident. In FIG. 1, the x-direction runs perpendicular to the plane of the drawing into the latter. The y-direction runs towards the left, and the z-direction runs upwards.

The object field 4 and the image field 8 are rectangular. In an alternative, it is also possible for the object field 4 and the image field 8 to have a bent or curved embodiment, i.e. be embodied in a partial ring shape for example. The object field 4 and the image field 8 have an x/y-aspect ratio of greater than 1. Therefore, the object field 4 has a longer object field dimension in the x-direction and a shorter object field dimension in the y-direction. These object field dimensions extend along the field coordinates x and y.

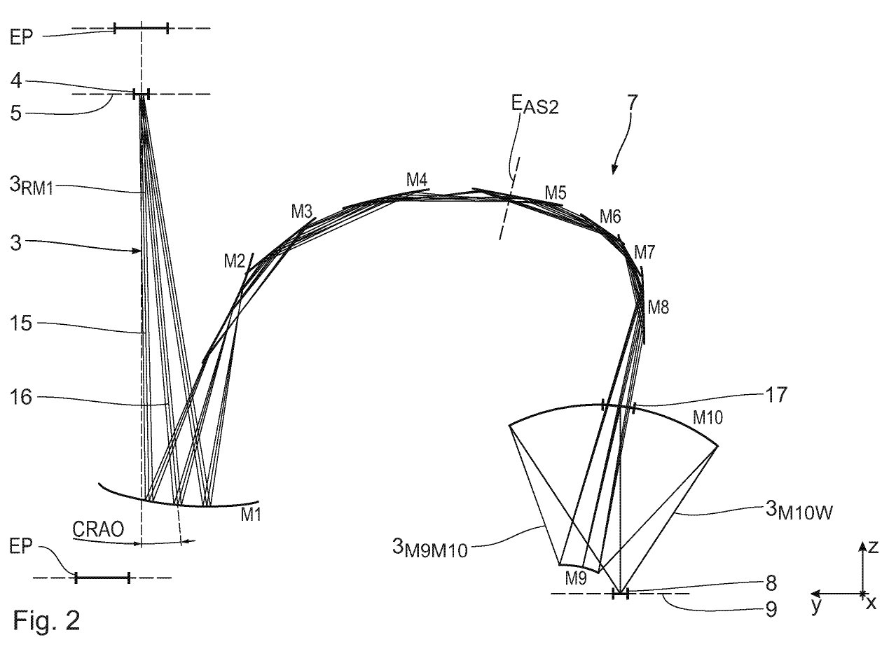

An exemplary embodiment depicted in FIG. 2 can be used for the projection optical unit 7. The projection optical unit 7 is anamorphic, i.e. it has a different reduction scale in the x-direction (reduction scale in the xz-plane) than in the y-direction (reduction scale in the yz-plane). The projection optical unit 7 has a reduction scale of 4 in the x-direction. The projection optical unit 7 has a reduction scale of 8 in the y-direction. Other reduction scales for the reduction in the x-direction and/or for the reduction in the y-direction are also possible, for example 4x, 5x or even reduction scales that are greater than 8x. An embodiment of the projection optical unit 7 with the same reduction scales as these, firstly, in the xz-plane and, secondly, in the yz-plane, i.e. an isomorphic embodiment, is also possible.

The image plane 9 is arranged parallel to the object plane 5 in the case of the projection optical unit 7. What is imaged in this case is a portion of a reflection mask 10, also referred to as reticle, coinciding with the object field 4. The reticle 10 is carried by a reticle holder 10a. The reticle holder 10a is displaced by a reticle displacement drive 10b.

The imaging by way of the projection optical unit 7 is implemented on the surface of a substrate 11 in the form of a wafer, which is carried by a substrate holder 12. The substrate holder 12 is displaced by a wafer or substrate displacement drive 12a.

FIG. 1 schematically depicts, between the reticle 10 and the projection optical unit 7, a beam 13 of illumination light 3 that enters into the projection optical unit and, between the projection optical unit 7 and the substrate 11, a beam 14 of illumination light 3 that emerges from the projection optical unit 7. An image field-side numerical aperture (NA) of the projection optical unit 7 is not reproduced to scale in FIG. 1.

The projection exposure apparatus 1 is of the scanner type. Both the reticle 10 and the substrate 11 are scanned in the y-direction during the operation of the projection exposure apparatus 1. A stepper type of the projection exposure apparatus 1, in which a stepwise displacement of the reticle 10 and of the substrate 11 in the y-direction is effected between individual exposures of the substrate 11, is also possible. These displacements are effected synchronously with one another by an appropriate actuation of the displacement drives 10b and 12a.

FIG. 2 shows the optical design of a first embodiment of the projection optical unit 7. FIG. 2 depicts the beam path of in each case three individual rays 15 emanating from a plurality of object field points which are spaced apart from one another in the y-direction in FIG. 2. Chief rays 16, i.e. individual rays 15 that pass through the centre of a pupil in a pupil plane of the projection optical unit 7, and an upper coma ray and a lower coma ray for each of these two object field points are depicted. Proceeding from the object field 4, the chief ray 16 of a central object field point makes an angle CRAO of 5.5° with a normal on the object plane 5.

The projection optical unit 7 has an image-side numerical aperture of 0.55.

An entrance pupil EP is arranged in the beam path of the imaging light 3 upstream of the object field 4. Possible positions of the entrance pupil EP above the object plane 5 with the use of a reticle 10 that transmits the imaging light 3 and below the object plane 5 with the use of a reflective reticle 10 are indicated in each case in FIG. 2. This results in a divergent extension of the chief rays 16 between the object field 4 and the mirror M1.

The projection optical unit 7 according to FIG. 2 has a total of ten mirrors, which are numbered consecutively by M1 to M10 in the order of the beam path of the individual rays 15, proceeding from the object field 4. The projection optical unit 7 is a purely catoptric optical unit. The imaging optical unit 7 can also have a different number of mirrors, for example four mirrors, six mirrors or eight mirrors. An odd number of mirrors is also possible in the projection optical unit 7.

FIG. 2 illustrates the calculated reflection surfaces of the mirrors M1 to M10. It is evident from the illustration according to FIG. 2 that only a portion of these calculated reflection surfaces is used. Only this actually used region of the reflection surfaces is actually present in the real mirrors M1 to M10. These used reflection surfaces are carried in a known manner by mirror bodies (not shown).

In the case of the projection optical unit 7 according to FIG. 2, the mirrors M1, M9 and M10 are embodied as normal incidence mirrors, i.e. as mirrors on which the imaging light 3 is incident at an angle of incidence less than 45°. Overall, the projection optical unit 7 according to FIG. 2 thus has three normal incidence mirrors M1, M9 and M10. Below, these mirrors are also referred to as NI mirrors.

The mirrors M2 to M8 are mirrors for grazing incidence of the illumination light 3, i.e. mirrors on which the illumination light 3 is incident at angles of incidence greater than 45°. A typical angle of incidence of the individual rays 15 of imaging light 3 on the mirrors M2 to M8 for grazing incidence is of the order of 80°. Overall, the projection optical unit 7 according to FIG. 2 has exactly seven mirrors M2 to M8 for grazing incidence. Below, these mirrors are also referred to as GI mirrors.

The mirrors M2 to M8 reflect the imaging light 3 such that the angles of reflection of the individual rays 15 at the respective mirrors M2 to M8 add up.

The mirrors M1 to M10 carry a coating that optimizes the reflectivity of the mirrors M1 to M10 for the imaging light 3. The coating can be, for example for the GI mirrors, a ruthenium coating, a molybdenum coating or a molybdenum coating with a topmost layer of ruthenium. Other coating materials can also be used. A coating having for example a layer of molybdenum or ruthenium can be used in the case of the grazing incidence mirrors M2 to M8. The highly reflecting layers, for example of the mirrors M1, M9 and M10 for normal incidence, can be configured as multi-lamina layers, wherein successive layers can be manufactured from different materials. Alternating material layers can also be used. A typical multi-lamina layer can have fifty bilayers, each made of a layer of molybdenum and a layer of silicon.

Information concerning reflection at a GI mirror (grazing incidence mirror) can be found in WO 2012/126867 A. Further information concerning the reflectivity of NI mirrors (normal incidence mirrors) can be found in DE 101 55 711 A.

An overall reflectivity or system transmission of the projection optical unit 7, emerging as a product of the reflectivities of all mirrors M1 to M10 of the projection optical unit 7, is approximately R = 8.49%.

The mirror M10, i.e. the last mirror upstream of the image field 8 in the imaging beam path, has a passage opening 17 for passage of the imaging light 3 which is reflected from the antepenultimate mirror M8 towards the penultimate mirror M9. The mirror M10 is used in a reflective manner around the passage opening 17. None of the other mirrors M1 to M9 has a passage opening and the mirrors are used in a reflective manner in a contiguous region without gaps.

The mirrors M1 to M10 are embodied as free-form surfaces which cannot be described by a rotationally symmetric function. Other embodiments of the projection optical unit 7, in which at least one of the mirrors M1 to M10 is embodied as a rotationally symmetric asphere, are also possible. It is also possible for all mirrors M1 to M10 to be embodied as such aspheres.

Free-form surfaces for reflection surfaces of the mirrors of projection optical units of microlithographic projection exposure apparatuses are known from US 2007 0 058 269 A1.

With regard to the arrangement and shape of the reflection surfaces of the mirrors M1 to M10, an embodiment of the projection optical unit 7 is known from WO 2016/188934 A1.

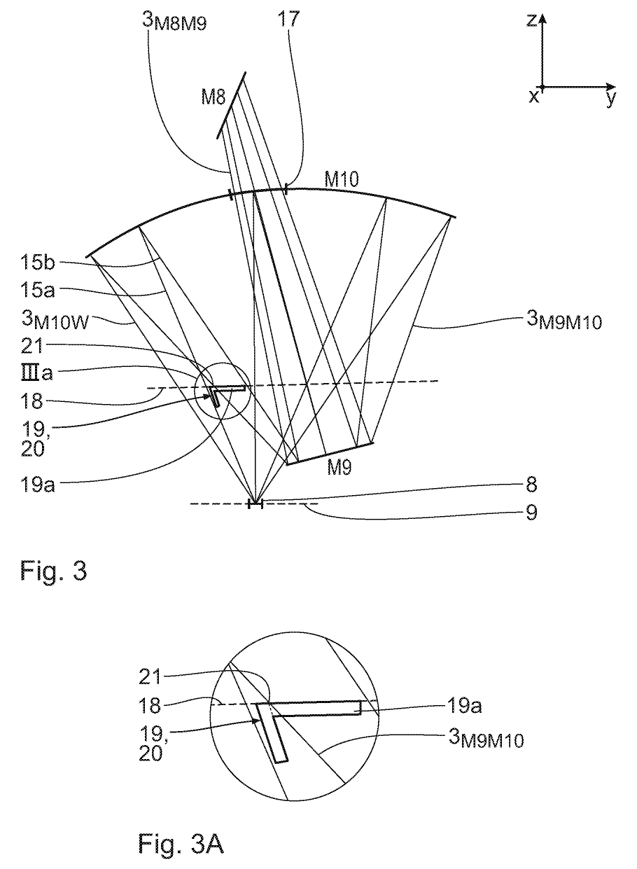

FIG. 3A shows a portion of the projection optical unit 7 in the region of the beam path between the mirror M8, which is only indicated schematically in FIG. 3A, and the image field 8. The illustration in FIG. 3A is schematic, for example, in so far as the mirrors M9 and M10 are depicted with plane reflection surfaces. In fact, these reflection surfaces are curved as per the embodiment for example according to FIG. 2 of WO 2016/188934 A1.

Three component beam paths, specifically a component beam path 3_{M8M9} between the mirrors M8 and M9, a component beam path 3_{M9M10} between the mirrors M9 and M10 and a component beam path 3_{M10W} between the mirror M10 and the image field 8, are depicted in FIG. 3A by outer marginal rays. In FIG. 2, a further component beam path 3_{RM1} is illustrated between the object field 4 and the mirror M1.

The component beam path 3_{M8M9} passes through the passage opening 17 in the last mirror M10 of the projection optical unit 7.

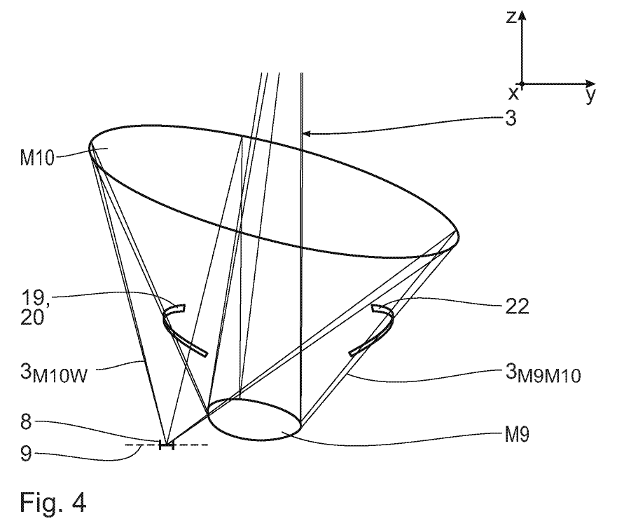

As evident from the meridional section according to FIG. 3A and also from the perspective illustration according to FIG. 4, the component beam path 3_{M10W} passes firstly through the component beam path 3_{M8M9} and secondly through the component beam path 3_{M9M10}.

An exit pupil plane 18 of the projection optical unit 7 is located in the component beam path 3_{M9M10}. In or near this exit pupil plane 18, a stop 19 is arranged in the component beam path 3_{M9M10} in such a way that, at least in portions, an outer edge contour of an exit pupil of the projection optical unit 7 in the component beam path 3_{M9M10} is also, by way of the the stop, specified in a pupil edge contour portion also located in the component beam path 3_{M10W} between the last mirror M10 and the image field 8 at the same time. Such a portion of the stop 19 is illustrated in the meridional sectional plane yz of FIG. 3A and is further illustrated, as regards the profile of the stop 19 along the pupil edge contour portion specified by the stop 19, by a stop portion 19a that follows this edge contour in the exit pupil plane 18.

The stop 19 is embodied as an aperture stop for specifying an image field-side numerical aperture of the projection optical unit 7.

Where it is also located in the component beam path 3_{M10W} at the same time, the stop 19 is embodied as a stop partial sleeve portion having at least one sleeve portion wall 20. This sleeve portion wall 20 specifies the outer edge contour of the pupil in the pupil edge contour portion (see the detail enlargement, FIG. 3B) by way of a light-determining edge 21 and is aligned such that it extends along the component beam path 3_{M10W}. In FIG. 3A, this is illustrated by two individual rays 15a, 15b of the component beam path 3_{M10W}, which both just pass the sleeve portion wall 20 of the stop 19 in the meridional plane yz of FIG. 3A. The sleeve portion wall20 of the stop 19 has a shading effect for the imaging light 3 only in the region of individual rays 15 located between the individual rays 15a and 15b within the meridional plane.

The sleeve portion wall 20 has a wall thickness less than 0.5 mm. This wall thickness can range from 50 µm to 500 µm.

On account of this alignment of the sleeve portion wall along the component beam path 3_{M10W} and the small wall thickness of the sleeve portion wall 20, the stop 19 shades less than 1% of the beam path 3_{M10W} within the image field-side numerical aperture specified by the stop 19.

Outside the pupil edge contour portion also located in the component beam path 3_{M10W} at the same time, the stop 19 transitions into a conventional stop portion 22 (cf. FIG. 4) which specifies the outer edge contour of the exit pupil of the projection optical unit 7 where the component beam path 3_{M9M10} is outside the beam path 3_{M10W}. This further stop portion 22 is carried by a stop carrier which in turn is connected to a frame component of the projection optical unit 7. The stop portion 22 also serves as a support component for the stop 19. The stop portion 22 is indicated only in regions in FIG. 4. The sleeve portion wall 20 of the stop 19 is also only indicated in regions in FIG. 4.

The stop 19 may be embodied together with the stop portion 22 in such a way that it specifies the entire outer edge contour of the exit pupil of the projection optical unit 7. The stop 19 can be embodied in one piece or in one part here. In a multi-part stop, a stop portion can also be arranged in the region of a further pupil plane E_{AS2}, which is located in the imaging beam path of the projection optical unit 7 in the region of a reflection at the mirror M5 (see FIG. 2).

In order to have a shading cross section that is as small as possible along the component beam path 3_{M10W}, the sleeve portion wall 20 can be embodied in the manner of a thin lamella.

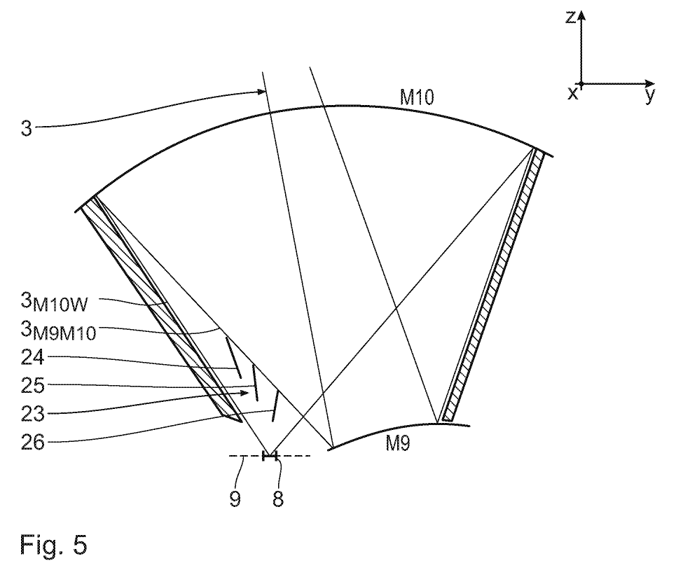

With reference to FIG. 5, explanations are given below as regards a further embodiment of a stop 23, which can be used instead of the stop 19. Components and functions that correspond to those which were already explained above even with reference to FIGS. 1-4 and for example with reference to FIGS. 3A and 4 have the same reference signs and are not discussed in detail again.

The stop 23 has a plurality of three stop partial sleeve portions 24, 25 and 26, and a total of three stop partial sleeve portions in the embodiment according to FIG. 5, each having a sleeve portion wall in the manner of the sleeve portion wall 20 of the embodiment according to FIGS. 3A and 4. These three stop partial sleeve portions 24 to 26 each at least in portions specify the outer edge contour of the exit pupil of the projection optical unit 7 in the pupil edge contour portion which is located in the component beam path 3_{M10W} between the last mirror M10 in the beam path and the image field 8 at the same time.

The stop partial sleeve portions 24 to 26 can complement one another with regard to their edge contour predetermination effect. For example, one of the stop partial sleeve portions, for example the stop partial sleeve portion 25, can be arranged exactly in the exit pupil plane 18 and the further stop partial sleeve portions, for example the stop partial sleeve portions 24 and 26, which are then arranged spaced apart from the exit pupil plane 18, can have a pupil predetermination effect where this is not possible by way of the stop partial sleeve portion 25 located in the pupil plane 18. At least one of the stop partial sleeve portions 24 to 26 can in turn be connected to a further stop portion in the manner of the stop portion 22 and can be held in this manner. In an alternative to that or in addition, the stop partial sleeve portions 24 to 26 can be connected to one another. An improved stray light suppression also emerges on account of the plurality of stop partial sleeve portions in the embodiment according to FIG. 5. The stop partial sleeve portions 24 to 26 are aligned in such a way that they follow a direction of light guidance in the component beam path 3_{M10W}. A shading effect of the stop partial sleeve portions 24 to 26 for imaging light guided in this component beam path 3_{M10W} is thus low and is negligible in many cases.

The plurality of stop partial sleeve portions 24 to 26 can be embodied in the manner of thin lamellas. The above explanations given as regards the sleeve portion wall 20 of the embodiment according to FIGS. 3A and 4 apply in this context and also in the context of the wall thickness of the respective sleeve portion wall of the stop partial sleeve portions 24 to 26.

The various sleeve portion walls of the stop partial sleeve portions 24 to 26 can specify the same pupil edge contour portion or else different pupil edge contour portions that can complement one another.

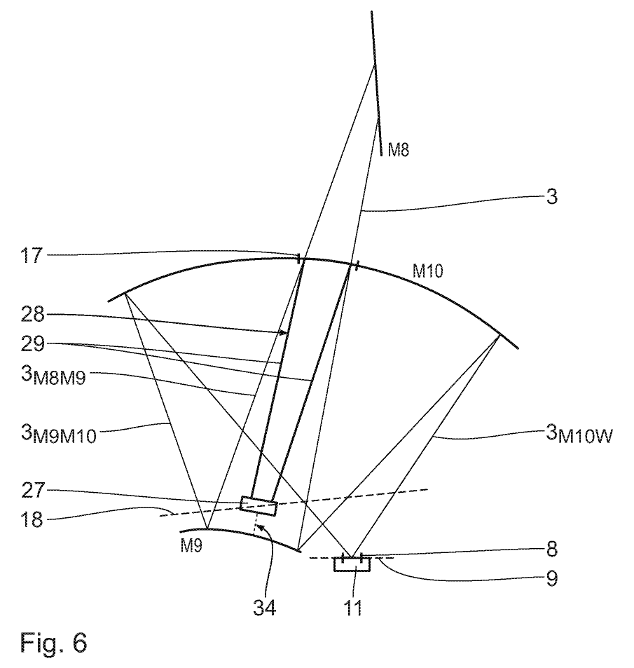

With reference to FIGS. 2 and 6, for example, explanations are given below as regards a further embodiment of a stop in the form of an obscuration stop, which can be used instead of the stop embodiments discussed above. Components and functions corresponding to those which have already been explained above with reference to FIGS. 1-5 bear the same reference signs and will not be discussed in detail again.

The exit pupil plane 18 (cf. FIG. 6) of the projection optical unit 7 is once again located in the beam path between the penultimate mirror M9 in the beam path, embodied without passage opening for the illumination light 3, and the last mirror M10 in the beam path, embodied with a passage opening 17 for the illumination light 3. An exit pupil in the exit pupil plane 18 is specified by way of embodiment variants of stops of the imaging optical unit presented below. In this case, an obscured exit pupil is specified, i.e. an exit pupil having an outer edge contour for specifying the image field-side numerical aperture of the projection optical unit 7 and having an inner edge contour for specifying a pupil obscuration of the projection optical unit 7.

One of the stops for specifying the edge contour of the pupil in the pupil plane 18 is an obscuration stop 27 (see FIG. 3A). The obscuration stop 27 serves to specify the pupil obscuration in the exit pupil plane 8. The obscuration stop 27 is arranged in the beam path of the projection optical unit 7 between the penultimate mirror M9 in the beam path and the last mirror M10 in the beam path. Due to the specification of the pupil obscuration, the obscuration stop 27 is embodied in such a way that it specifies portions of an edge contour of the exit pupil of the projection optical unit 7 in the beam path between the mirror M9 and the mirror M10, specifically the inner edge contour of the exit pupil.

FIG. 6 shows a first variant of fastening the obscuration stop 27. The latter is fastened to the last mirror M10 in the beam path of the projection optical unit 7 by way of a securing element 28. The latter has a plurality of securing connecting pieces 29, of which two securing connecting pieces 29 are depicted in FIG. 6. The number of securing connecting pieces 29 can lie in the range between one and ten, for example. For example, three, four or six such securing connecting pieces 29 can be used depending on the embodiment of the securing element 28.

The respective securing connecting piece 29 is fastened at one connecting piece end to a main body of the obscuration stop 27 and at the other end to the edge of the passage opening 17 in the last mirror M10. The securing connecting pieces 29 of the securing element 28 are thin and can have a maximum diameter less than 0.5 mm. Fastening points of the securing connecting pieces 29 on the main body of the obscuration stop 27 are spaced apart from an edge of the obscuration stop 27 used for specifying the pupil edge contour. This edge used to specify the pupil edge contour is also referred to as the light-determining stop edge.

The obscuration stop 27 and also the embodiments of the stops described below have a light-determining stop edge for specifying the respective pupil edge contour, the stop edge possibly making an edge angle in the range between 20° (pointed stop edge) and 70° (blunt stop edge) with respect to the respective edge contour.

FIG. 6 illustrates an extension of the beam path of the projection optical unit 7 between the mirror M8 only indicated in FIG. 6 and the image field 8 by marginal rays. This extension is divided into three component beam paths, specifically the component beam path 3_{M8M9} between the mirrors M8 and M9, the component beam path 3_{M9M10} between the mirrors M9 and M10 and the component beam path 3_{M10W} between the mirror M10 and the image field 8, i.e. between the mirror M10 and the wafer 11.

The obscuration stop 27 serves to shade the component beam path 3_{M9M10} in the exit pupil plane 18.

The securing connecting pieces 29 of the securing element 28 extend along the component beam path 3_{M8M9} between the mirrors M8 and M9 on the one hand and along the component beam path 3_{M9M10} between the mirrors M9 and M10 on the other hand, i.e., for example, along the component beam path 3_{M9M10} between the penultimate mirror M9 in the beam path and the last mirror M10 in the beam path. In any case, in the component beam path 3_{M8M9} between the mirrors M8 and M9, the securing connecting pieces 29 extend mostly in the region of the beam path shaded by the obscuration stop 27, and so these parts of the securing connecting pieces 29 do not bring about any attenuation of the illumination light 3 in the beam path between the mirrors M8 and M9.

The securing connecting pieces 29 can have a rigid embodiment overall, i.e. can absorb tensile forces and compressive forces for fastening the obscuration stop 27 relative to the mirror M10. In an alternative embodiment, at least one of the securing connecting pieces 29 is made of a flexurally slack material in such a way that only tensile forces can be transmitted through this securing connecting piece, but no compressive forces.

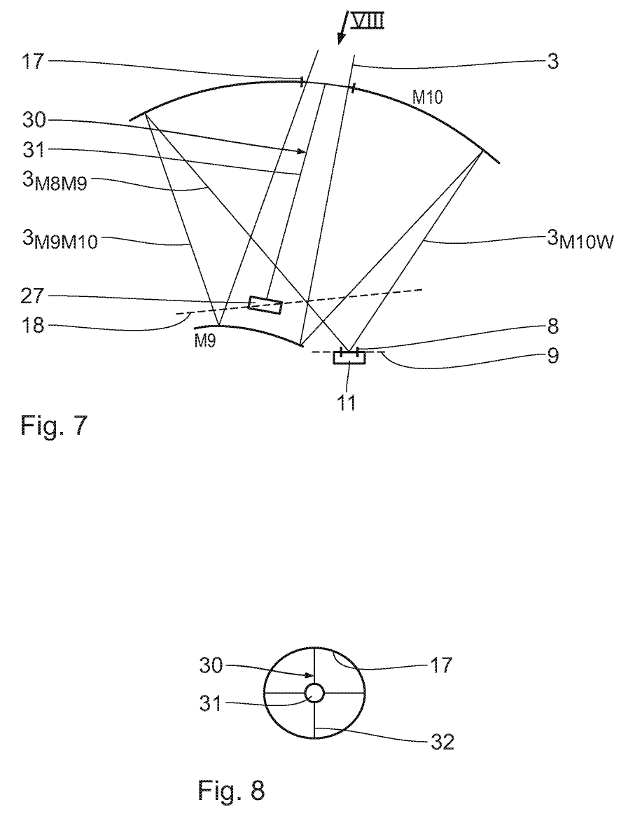

FIGS. 7 and 8 show a further embodiment of fastening the obscuration stop 27. In this embodiment, a securing element 30 is used to fasten the obscuration stop 27. The latter has a securing connecting piece in the form of a central connecting piece 31, which at one end is connected to a central portion of the obscuration stop 27 and at the other end extends up to the passage opening 17 of the mirror M10. There, the central connecting piece 31 is connected to a plurality of securing connecting pieces in the form of connecting pieces 32 which fasten a passage opening-side end of the central connecting piece 31 to the edge of the passage opening 17. The connecting pieces 32 extend radially in the passage opening 17. The connecting pieces 32 have a maximum connecting piece diameter which is less than 0.5 mm and can also be less than 0.25 mm and can also be less than 0.1 mm. Typically, the connecting pieces 32 have a maximum connecting piece diameter which is greater than 0.02 mm.

A maximum connecting piece diameter of the central connecting piece 31 can be a multiple of the maximum connecting piece diameter of the connecting pieces 32 and can, for example, be twice as large or else five times as large as the maximum connecting piece diameter of the connecting pieces 32.

Exactly four connecting pieces 32 are shown in the embodiment according to FIG. 8. The number of connecting pieces 32 can range between three and ten, depending on the embodiment of the securing element 30. For example, six or eight such connecting pieces 32 can also be used depending on the embodiment of the securing element 30.

The central connecting piece 31 extends along the beam path between the mirrors M8 and M9 and extends there overall in a cross section of the beam path of the projection optical unit 7 obscured by the obscuration stop 27. Effectively, a throughput of the illumination light 3 through the projection optical unit 7 in the beam path between the mirrors M8 and M9 is thus not reduced by the central connecting piece 31.

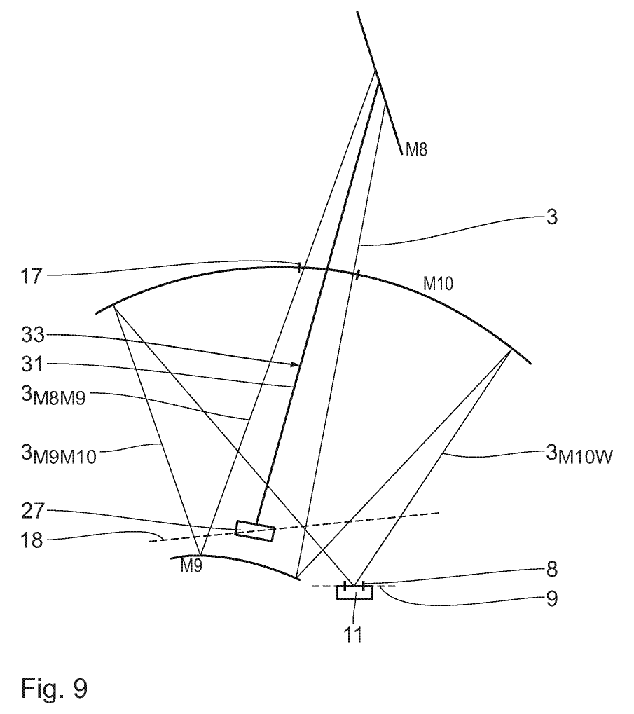

FIG. 9 shows a further embodiment of fastening the obscuration stop 27. A securing element 33 for its fastening is affixedly fastened in the form of a securing connecting piece between the obscuration stop 27 and the antepenultimate mirror M8 of the projection optical unit 7 and has, like the central connecting piece 31 of the securing element 30 according to FIGS. 7 and 8, an extension along the beam path between the mirrors M8 and M9. This extension may be located completely within a portion of the beam path of the imaging optical unit 7 obscured by the obscuration stop 27, and so the securing element 33 does not attenuate the illumination light along this part of the beam path between the mirrors M8 and M9.

Overall, the securing element 33 is embodied as a securing connecting piece. The explanations given above as regards the central connecting piece 31 of the securing element 30 according to FIGS. 7 and 8 apply to the strength of this securing connecting piece.

In an embodiment not shown in the drawing, a securing element in the manner of the securing element 33 according to FIG. 9 can also be secured to a frame component of the imaging optical unit 7.

In an embodiment of a securing element 34 which is shown with dashes in FIG. 6 and can be used in an alternative or in addition to the above-explained securing elements 28, 30 and 33, the obscuration stop 27 is fastened to the penultimate mirror M9 in the beam path of the projection optical unit 7. The securing element 34 in turn is embodied as a securing connecting piece overall, connected at one end to a central region of the obscuration stop 27 and at the other end to a region of a reflection surface of the mirror M9 shaded by the obscuration stop 27. The securing element 34 in turn extends at least in portions along the beam path between the mirrors M8 and M9 and along the beam path between the mirrors M9 and M10. This extension may be such that the securing element 34 overall does not attenuate the illumination light in the beam path of the projection optical unit 7 between the mirrors M8 and the image field 8.

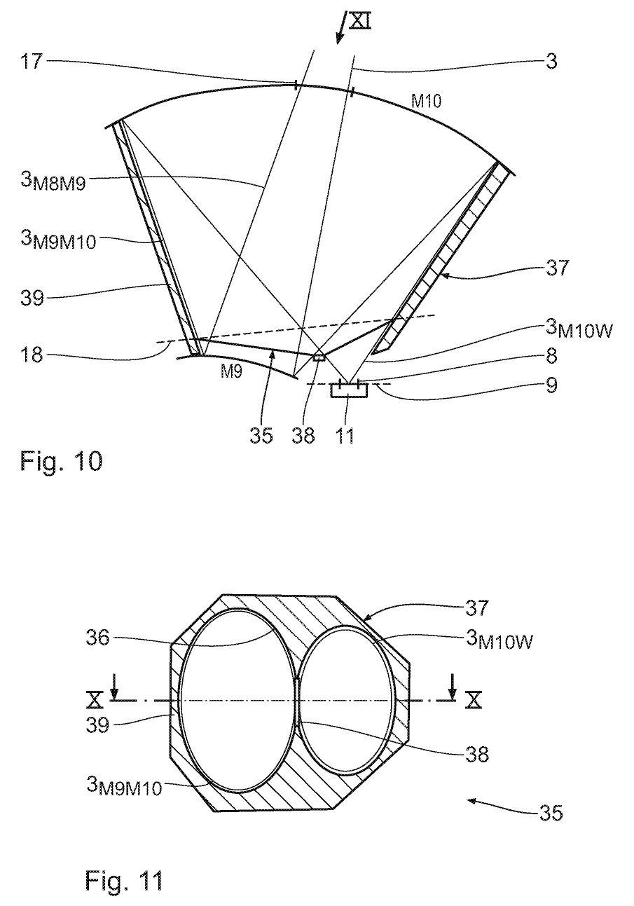

With reference to FIGS. 10 and following, embodiments of an arrangement or fastening of an aperture stop for at least portion-wise specification of the edge contour of an exit pupil of the projection optical unit 7 in the beam path between the penultimate mirror M9 in the beam path and the last mirror M10 in the beam path are described below.

FIG. 10 shows an embodiment of an aperture stop 35 in a meridional section comparable for example to FIG. 6, and FIG. 11 shows a plan view of components of the aperture stop 35 serving to specify the image field-side numerical aperture of the projection optical unit 7.

The aperture stop 35 specifies an outer edge contour 36 of the exit pupil in the beam path between the penultimate mirror M9 in the beam path and the last mirror M10 in the beam path. Marginal rays of this component beam path 3_{M9M10} are illustrated in FIGS. 2 and 6ff and for example also in FIGS. 10 and 11.

The aperture stop 35 is part of an enveloping component 37 of the projection optical unit 7 that surrounds the component beam paths 3_{M9M10} between the mirrors M9 and M10 and 3_{M10W} between the mirror M10 and the wafer 11. This enveloping component 37 surrounds the component beam paths 3_{M9M10} between the mirrors M9 and M10 on the one hand and 3_{M10W} in a three-dimensionally adapted shape, and thus does not surround these two component beam paths 3_{M9M10}, 3_{M10W} in full in the exit pupil plane 18. In the region of an aperture stop connecting piece 38 between the two component beam paths 3_{M9M10} and 3_{M10W}, which is part of the aperture stop 35, the enveloping component 37 and hence also the aperture stop 35 extend at a distance from the exit pupil plane 18 (cf. FIG. 10).

Between the aperture stop connecting piece 38 and an aperture stop portion 39 opposite the component beam path 3_{M9M10}, the enveloping component 37 that surrounds the component beam path 3_{M9M10} approaches the exit pupil plane 18, wherein the aperture stop 37 is then located in the exit pupil plane 18 in portions.

The enveloping component 37 has the additional function of a beam path enclosure. The enveloping component 37 prevents particles from accumulating on the reflection surfaces of the mirrors M9 and M10. The enveloping component 37 can be embodied such that a certain hydrogen partial pressure is present therein, the the hydrogen partial pressure having a cleaning effect for the reflection surfaces of the mirrors of the imaging optical unit 7 and/or preventing contamination of the mirrors. The enveloping component 37 also has the function of absorbing stray light. The enveloping component 37 may have a coating which acts as a contamination absorber where it faces the respective component beam paths 3_{MIMJ} (component beam path between the respective mirrors MI and MJ) or 3_{RM1} (component beam path between the reticle 10 and the mirror M1) and 3_{M10W}. On such a coating, possible particles can then be accumulated in comparison with the mirror reflection surfaces, and this additionally prevents contamination of the mirrors.

Overall, the aperture stop 35 according to FIGS. 10 and 11 is part of the enveloping component 37 that surrounds the component beam path 3_{M9M10}.

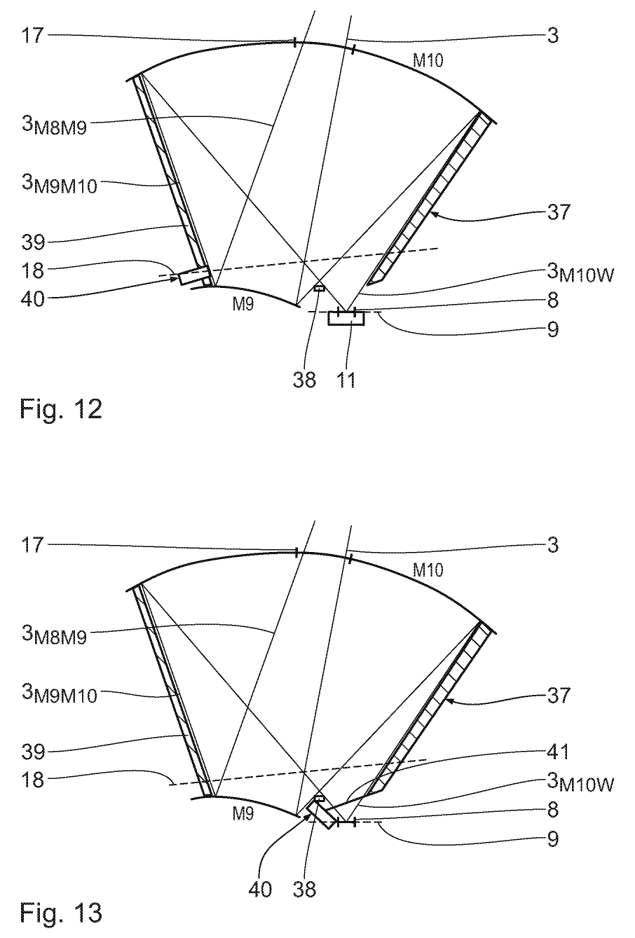

A further embodiment of an aperture stop 40 and fastening thereof is described with reference to FIGS. 12 and 13; in terms of its function, the the aperture stop corresponds to the aperture stop 35 according to FIGS. 10 and 11. Components and functions that correspond to those which were explained above with reference to FIGS. 1-11 and for example with reference to FIGS. 10 and 11 have the same reference signs and are not discussed in detail again.

The aperture stop 40 having the aperture stop connecting piece 38 (see FIG. 13) and the aperture stop portion 39 (see FIG. 12) has the same extension as the aperture stop 35 with respect to the specification of the outer edge contour of the exit pupil of the projection optical unit 7. The aperture stop 40 is fastened to the enveloping component 37. In the embodiment according to FIGS. 12 and 13, the aperture stop 40 is therefore not a constituent part of the enveloping component 37, but a separate component therefrom, which is fastened to the enveloping component 37. A variant of a securing element 41 for fastening the aperture stop connecting piece 38 to the enveloping component 37 is illustrated in FIG. 13. The securing element 41 is a securing connecting piece which is connected at one end to the aperture stop connecting piece 38 and at the other end to an edge portion of the enveloping component 37. The securing element 41 may overall extend outside the beam path of the projection optical unit 7.

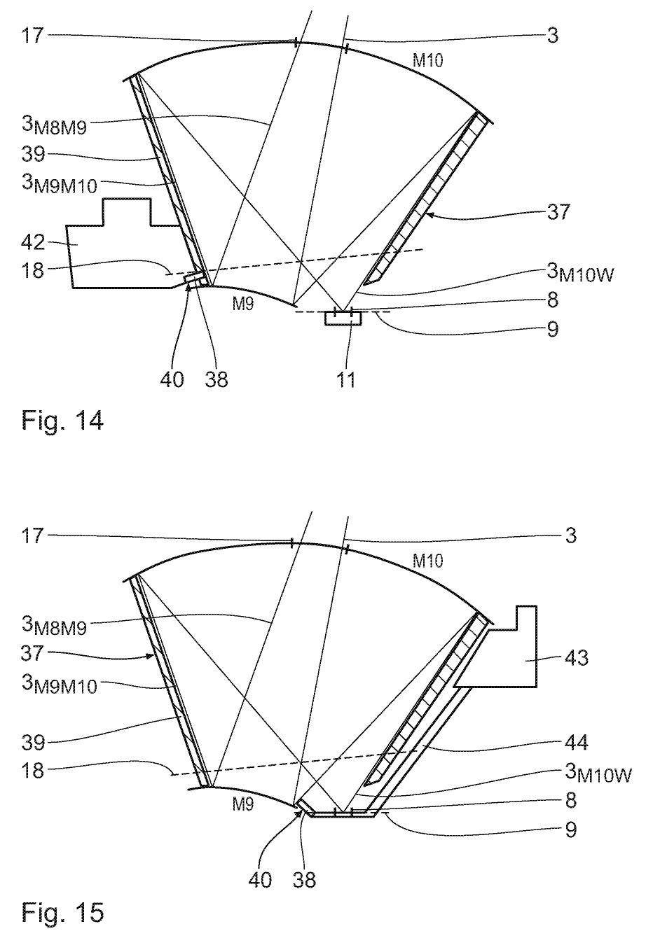

FIG. 14 shows an alternative option of fastening the aperture stop portion 39. Components and functions that correspond to those which were explained above with reference to FIGS. 1-13 and for example with reference to FIG. 12 have the same reference signs and are not discussed in detail again.

In the embodiment according to FIG. 14, the aperture stop portion 39 is fastened directly to a frame component 42 of the projection optical unit 7. This frame component 42 also carries the penultimate mirror M9.

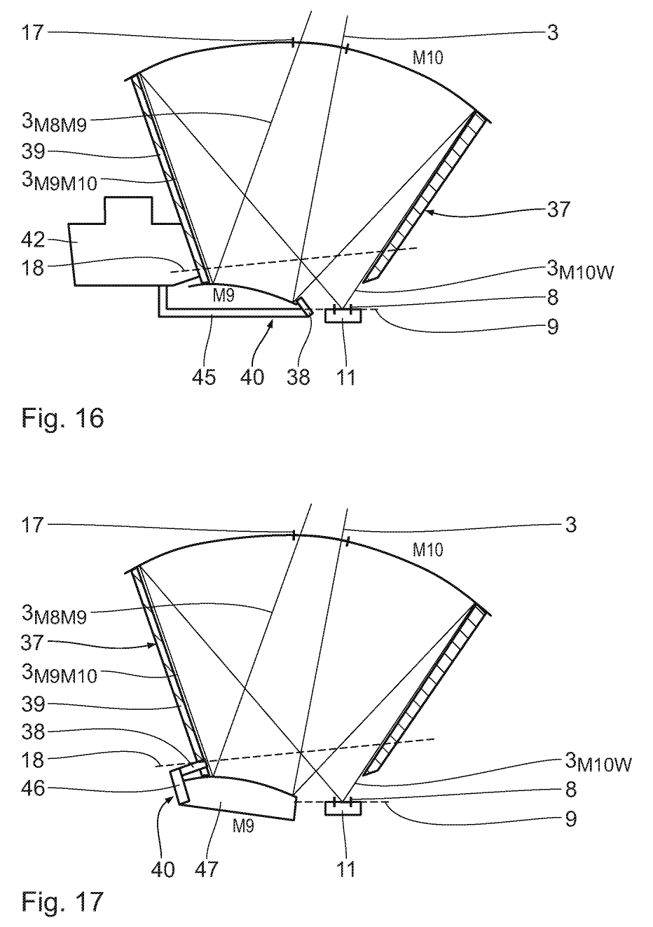

FIGS. 15 and 16 show two variants for fastening the aperture stop connecting piece 38, once again to a frame component of the projection optical unit 7. In the embodiment according to FIG. 15, the aperture stop connecting piece 38 is fastened to a frame component 43 of the projection optical unit 7 which also carries the last mirror M10. A securing element 44 is used for fastening purposes, the the securing element being connected at one end to the frame component 43 and at the other end to the aperture stop connecting piece 38. This securing element 44 may overall extend outside the beam path of the projection optical unit 7.

FIG. 16 shows alternative fastening of the aperture stop connecting piece 38 to the frame component 42 by way of a securing element 45. The latter is connected at one end to the frame component 42 and at the other end to the aperture stop connecting piece 38.

Components and functions of FIGS. 14-16 which were explained above and with reference to FIGS. 1-13 have the same reference signs and will not be discussed in detail again.

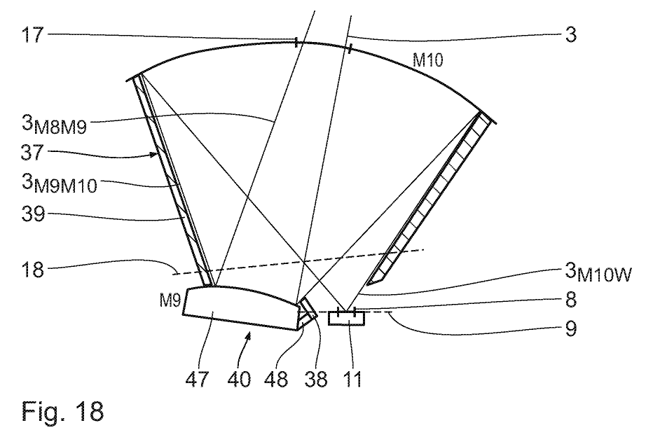

A further embodiment of fastening the aperture stop 40 to the penultimate mirror M9 in the beam path is explained below with reference to FIGS. 17 and 18. Components and functions corresponding to those which have already been explained above with reference to FIGS. 1-16 bear the same reference signs and will not be discussed in detail again.

FIG. 17 shows fastening of the aperture stop portion 39 via a securing element 46, which is connected at one end to the aperture stop portion 39 and at the other end to a mirror body 47 of the penultimate mirror M9 in the beam path. FIG. 18 shows fastening of the aperture stop connecting piece 38 by way of a securing element 48, which is connected at one end to the aperture stop connecting piece 38 and at the other end to the mirror body 47. The securing elements 46, 48 can be arranged completely outside the beam path of the projection optical unit 7.

In an alternative, the aperture stop 40 may also be fastened for example to the last mirror in the beam path by way of appropriate securing elements, which are connected at one end to corresponding portions of the aperture stop 40 and at the other end to a mirror body of the last mirror M10 of the projection optical unit 7 in the beam path.

The various arrangement and fastening variants of the obscuration stop 27 on the one hand and of the aperture stops 35, 40 on the other hand explained above in each case ensure a secure and precise fastening of the respective stop within the beam path of the imaging light 3 of the projection optical unit 7.

In so far as one of the above-described securing elements for the respective stop is arranged in the beam path between the last mirror M10 in the beam path and the image field 8, the the securing element shades less than 1% of the beam path between the last mirror M10 and the image field 8 within the image field-side numerical aperture specified by the respective stop.

The respective securing elements can be embodied with an actuator for displacing the respective aperture stop portion relative to the respective holding part to which the respective aperture stop portion is fastened, i.e. relative for example to the enveloping component 37 or else to the respective frame component 42 or 43 or to the respective mirror M8, M9 or M10. For example, an actuator-based relative displaceability in relation to the mirrors M8, M9 or M10 as fastening components ensures that positioning of the respective stop portion can be implemented independently of a displacement of the respective mirror. For example, a forced displacement of the stop during an adjustment displacement of the mirror to which the stop is fixed can then be compensated again via an actuator-based correction in which the stop is displaced relative to this mirror.

The embodiments of the imaging optical units described above, for example the stop arrangements and stop holders, can also be embodied in a combined form.

In order to produce a microstructured or nanostructured component, the projection exposure apparatus 1 is used as follows: first, the reflection mask 10 or the reticle and the substrate or the wafer 11 are provided. Subsequently, a structure on the reticle 10 is projected onto a light-sensitive layer of the wafer 11 with the aid of the projection exposure apparatus 1. Then a microstructure or nanostructure on the wafer 11, and hence the microstructured component, is produced by developing the light-sensitive layer.

What is claimed is:

1. An imaging optical unit, comprising:
a plurality of mirrors configured to image an object field in an object plane into an image field in an image plane with imaging light guided along a beam path between the object field and the image field, the plurality of mirrors comprising a penultimate mirror in the beam path and a last mirror in the beam path, the penultimate mirror being without an opening configured to pass the imaging light; and
a stop in the beam path between the penultimate mirror and the last mirror, wherein:
the stop is configured to specify an outer edge contour of a pupil of the imaging optical unit in the beam path between the penultimate mirror and the last mirror at least in one pupil edge contour portion disposed in the beam path between the last mirror and the image field.

2. The imaging optical unit of claim 1, wherein the stop is configured to shade less than 1% of the beam path between the last mirror and the image field within an image field-side numerical aperture specified by the stop.

3. The imaging optical unit of claim 1, wherein the stop comprises a partial sleeve portion comprising a sleeve portion wall configured to specify the outer edge contour of the pupil in the pupil edge contour portion, the sleeve portion wall extending along the beam path between the last mirror and the image field.

4. The imaging optical unit of claim 3, wherein a wall thickness of the sleeve portion wall is less than 0.5 millimeter.

5. The imaging optical unit of claim 1, wherein the stop comprises a plurality of stop partial sleeve portions each comprising a sleeve portion wall, which in each case is configured to specify, at least in portions, the outer edge contour of the pupil in the pupil edge contour portion, each sleeve portion wall extending along the beam path between the last mirror and the image field.

6. The imaging optical unit of claim 5, wherein the stop partial sleeve portions are connected to one another.

7. The imaging optical unit of claim 1, wherein the last mirror comprises an opening configured to pass the imaging light.

8. The imaging optical unit of claim 1, wherein the stop covers the outer edge contour of the pupil in an azimuth range, greater than 180°, around a center of the pupil.

9. The imaging optical unit of claim 1, wherein the stop is configured to specify the entire outer edge contour of the pupil of the imaging optical unit.

10. An imaging optical unit, comprising:
a plurality of mirrors configured to image an object field in an object plane into an image field in an image plane with imaging light guided along a beam path between the object field and the image field, the plurality of mirrors comprising a penultimate mirror in the beam path and a last mirror in the beam path, the penultimate mirror being without an opening configured to pass the imaging light;
a stop in the beam path between the penultimate mirror and the last mirror; and
a securing element which, at least in portions, extends along the beam path between the penultimate mirror, wherein:
the stop is configured to specify an outer edge contour of a pupil of the imaging optical unit in the beam path between the penultimate mirror and the last mirror, at least in portions;
the securing element fastens the stop to a mirror of the plurality of mirrors.

11. The imaging optical unit of claim 10, wherein the pupil of the imaging optical unit is obscured, and the stop is configured to specify an inner edge contour of the obscured pupil of the imaging optical unit in the beam path between the penultimate mirror and the last mirror.

12. The imaging optical unit of claim 1, wherein the securing element is fastened to:
the last mirror; or
the penultimate mirror; or
an antepenultimate mirror in the beam path; or
a frame component of the imaging optical unit.

13. An imaging optical unit, comprising:
a plurality of mirrors configured to image an object field in an object plane into an image field in an image plane with imaging light guided along a beam path between the object field and the image field, the plurality of mirrors comprising a penultimate mirror in the beam path and a last mirror in the beam path, the penultimate mirror being an opening configured to pass the imaging light; and
a stop in the beam path between the penultimate mirror and the last mirror, wherein the stop is:
part of an enveloping component of the imaging optical unit surrounding the beam path;
fastened to an enveloping component of the imaging optical unit surrounding the beam path;
fastened to a frame component of the imaging optical unit; or
fastened to the penultimate mirror; or
fastened to the last mirror.

14. The imaging optical unit of claim 10, wherein the securing element configured to:
fasten the stop to the enveloping component surrounding the beam path; or
fasten the stop to the frame component; or
fasten to the antepenultimate mirror in the beam path; or
fasten to the penultimate mirror in the beam path; or
fasten to the last mirror in the beam path; or
wherein the securing element is located at least in portions in the beam path between the last mirror and the image field.

15. The imaging optical unit of claim 14, wherein the securing element is configured to shade less than 1% of the beam path between the last mirror and the image field within an image field-side numerical aperture specified by the stop.

16. The imaging optical unit of claim 14, wherein a wall thickness of the securing element is less than 0.5 mm.

17. The imaging optical unit of claim 14, wherein the last mirror comprises an opening configured to pass the imaging light.

18. The imaging optical unit of claim 10, wherein the stop is configured to cover an outer edge contour of the pupil in an azimuth range, greater than 180°, around a centre of the pupil.

19. The imaging optical unit of claim 10, wherein the stop is configured to specify the entire outer edge contour of the pupil and/or that it specifies the entire inner edge contour of the pupil.

20. An optical system, comprising:
an illumination optical unit configured to illuminate the object field with the imaging light; and
an imaging optical unit according to claim 1.

21. An optical system, comprising:
an illumination optical unit configured to illuminate the object field with the imaging light; and
an imaging optical unit according to claim 10.

22. An optical system, comprising:
an illumination optical unit configured to illuminate the object field with the imaging light; and
an imaging optical unit according to claim 13.

23. An optical system, comprising:
an imaging optical unit according to claim 1; and
a wafer holder which is displaceable in a first direction,
wherein the stop is configured to delimit both extreme edge positions of the outer edge contour of the pupil of the imaging optical unit in a direction perpendicular to the first direction.

24. An optical system, comprising:
an imaging optical unit according to claim 10; and
a wafer holder which is displaceable in a first direction,
wherein the stop is configured to delimit both extreme edge positions of the outer edge contour of the pupil of the imaging optical unit in a direction perpendicular to the first direction.

25. An optical system, comprising:
an imaging optical unit according to claim 13; and
a wafer holder which is displaceable in a first direction,
wherein the stop is configured to delimit both extreme edge positions of the outer edge contour of the pupil of the imaging optical unit in a direction perpendicular to the first direction.

26. A projection exposure apparatus, comprising an optical system and an EUV light source, wherein the optical system comprises:
an illumination optical unit configured to illuminate the object field with the imaging light; and
an imaging optical unit according to claim 1.

27. A projection exposure apparatus, comprising an optical system and an EUV light source, wherein the optical system comprises:
an imaging optical unit according to claim 1; and
a wafer holder which is displaceable in a first direction,
wherein the stop is configured to delimit both extreme edge positions of the outer edge contour of the pupil of the imaging optical unit in a direction perpendicular to the first direction.

28. A method, comprising:
providing a reticle and a wafer;
projecting a structure on the reticle onto a light-sensitive layer of the wafer using a projection exposure apparatus; and
creating a microstructure or nanostructure on the wafer,
wherein the projection exposure apparatus comprises:
an optical system; an EUV light source,
wherein the optical system comprises:
an imaging optical unit according to claim 1; and
a wafer holder which is displaceable in a first direction, and
wherein the stop is configured to delimit both extreme edge positions of the outer edge contour of the pupil of the imaging optical unit in a direction perpendicular to the first direction.

29. A method, comprising:
providing a reticle and a wafer;
projecting a structure on the reticle onto a light-sensitive layer of the wafer using a projection exposure apparatus; and
creating a microstructure or nanostructure on the wafer,
wherein the projection exposure apparatus comprises:
an optical system; an EUV light source,
wherein the optical system comprises:
an illumination optical unit configured to illuminate the object field with the imaging light; and
an imaging optical unit according to claim 1,
according to claim 20 or 21 and having an EUV light source (2).
